(19) United States
(12) Patent Application Publication
(10) Pub. No.: US 2003/0213891 A1
(43) Pub. Date: Nov. 20, 2003

(54) Image sensor

(76) Inventors: Jason Chuang, Hsinchu Hsien (TW); Jichen Wu, Hsinchu Hsien (TW); Jachson Hsieh, Hsinchu Hsien (TW)

Correspondence Address: Keith Kline, PRO-TECHTOR INTERNATIONAL SERVICES, 20775 Norada court, Saratoga, CA, 95070-3018, US

(21) Appl. No.: 10/146,997

(22) Filed: May 15, 2002

(51) Int. Cl. H01L 27/00

(52) U.S. Cl. 250/208.1

(57) ABSTRACT

The invention provides an image sensor including a substrate, a frame layer, a photosensitive chip, a plurality of wires, and a transparent layer. The substrate includes plural metal sheets, which are spaced apart and arranged in an alternating manner. Each of the metal sheets includes a first board and a second board positioned at different heights. The frame layer is formed around and under the substrate to form a cavity with the substrate. Each of the first boards has a top surface exposed from the frame layer while each of the second boards has a bottom surface, which is exposed from the frame layer and serves as contact points for signal outputs. The photosensitive chip is positioned within the cavity. The wires electrically connect the top surfaces of the first boards to the photosensitive chip. The transparent layer is placed on the frame layer to cover the photosensitive chip. According to the invention, the manufacturing cost can be effectively lowered and the production yield can be improved.

### BACKGROUND OF THE INVENTION

1. Field of the Invention

The invention relates to an image sensor, and more specifically to an image sensor which can be manufactured conveniently and improve the product yield.

2. Description of the Related Art

Referring to FIGS. 1 and 2, a conventional package structure for photosensitive chips is manufactured according to the following steps. First, a substrate 10, on which traces 12 are formed to define a plurality of zones 17, is provided. Then, a plurality of photosensitive chips 13 is arranged in the plurality of zones 17. Next, a frame layer 14 formed with a plurality of slots 16 corresponding to the traces 12 is adhered onto the substrate 10 via an adhesive layer 15. At this time, the photosensitive chips 13 on the substrate 10 are exposed via the slots 16. Then, a plurality of wires 18 is provided to electrically connect the photosensitive chips 13 to the substrate 10. Next, the substrate 10 is cut into package bodies each including the frame layer 14, as shown in FIG. 2. Then, as shown in FIG. 3, a single package body is placed within a jig 22, and a zone for receiving a transparent glass 20 is defined. Next, the transparent glass 20 covers the frame layer 14 to finish the package processes of the photosensitive chips 13.

However, the conventional image sensor has the following drawbacks, thereby resulting in the high package cost.

1. The substrate 10 has to be manufactured in advance. Then, the traces 12 are formed on the substrate 10. Subsequently, the frame layer 14 is bonded to the substrate 10. Therefore, the manufacturing processes are relatively complicated and the material cost is also high, thereby increasing the overall manufacturing cost.

2. After having been packaged, the image sensors have to be cut into individual package bodies. Since the frame layer 14 is bonded to the substrate 10 by the adhesive layer 15, the adhesive layer 15 tends to overflow during the cutting process, thereby influencing the signal transmission effect.

3. The process for covering the transparent glass 20 is performed after the substrate 10 is cut, the photosensitive chips 13 are easy to be contaminated by the cutting chips. As a result, the yield of the photosensitive chips 13 is adversely influenced.

In view of the above-mentioned problems, the invention provides an image sensor capable of improving the drawbacks to make the image sensor more practical.

### SUMMARY OF THE INVENTION

It is therefore an object of the invention to provide an image sensor capable of simplifying the packaging processes to decrease the manufacturing cost.

It is another object of the invention to provide an image sensor capable of increasing the production yield to decrease the packaging cost.

To achieve the above-mentioned objects, the invention provides an image sensor including a substrate, a frame layer, a photosensitive chip, a plurality of wires, and a transparent layer. The substrate includes plural metal sheets, which are spaced apart and arranged in an alternating manner. Each of the metal sheets includes a first board and a second board positioned at different heights. The frame layer is formed around and under the substrate to form a cavity with the substrate. Each of the first boards has a top surface exposed from the frame layer while each of the second boards has a bottom surface, which is exposed from the frame layer and serves as contact points for signal outputs. The photosensitive chip is positioned within the cavity. The wires electrically connect the top surfaces of the first boards to the photosensitive chip. The transparent layer is placed on the frame layer to cover the photosensitive chip. According to the invention, the manufacturing cost can be effectively lowered and the production yield can be improved.

### BRIEF DESCRIPTION OF THE DRAWINGS

FIG. 1 is an exploded view showing a conventional package structure for photosensitive chips.

FIG. 2 is a first schematic illustration showing the conventional package structure for photosensitive chips during the package processes.

FIG. 3 is a second schematic illustration showing the conventional package structure for photosensitive chips during the package processes.

FIG. 4 is a cross-sectional view showing the image sensor of the invention.

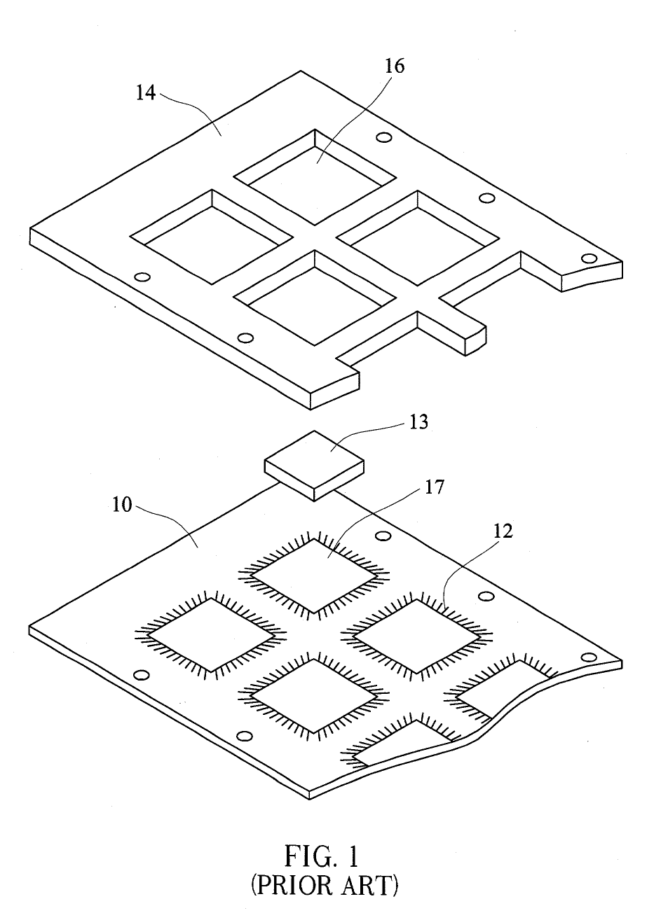

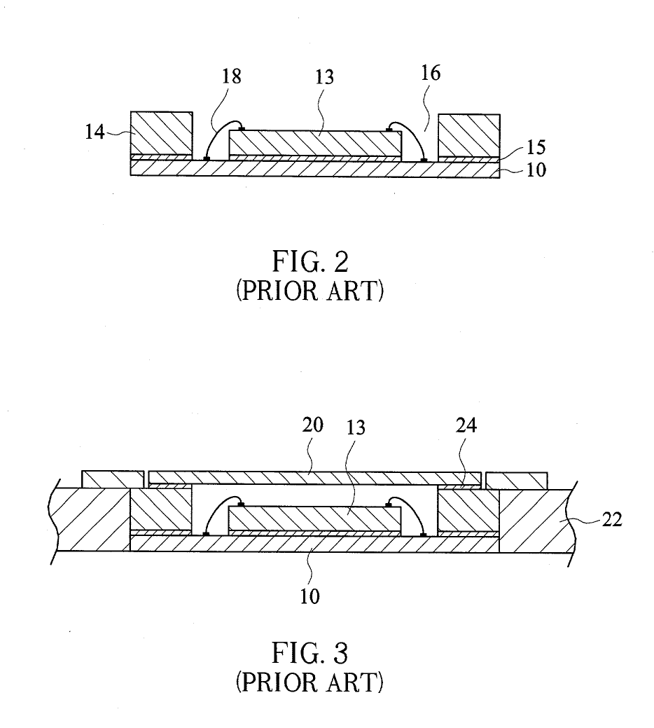

### DETAILED DESCRIPTION OF THE INVENTION

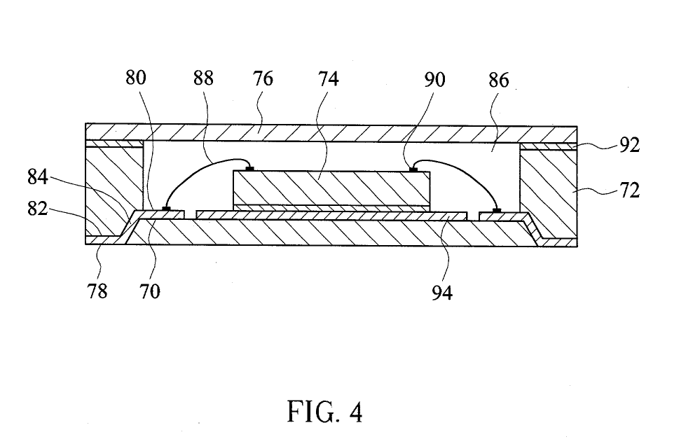

Referring to FIG. 4, the image sensor in accordance with one embodiment of the invention includes a substrate 70, a frame layer 72, a photosensitive chip 74, a plurality of wires 88 and a transparent layer 76.

The substrate 70 is consisted of a plurality of metal sheets 78, which are arranged in an alternating manner, and a middle board 94, which is arranged in the center of a zone enclosed by the metal sheets 78 and apart from the metal sheets 78. Each metal sheet 78 includes a first board 80, a second board 82, and a third board 84 connecting the first board 80 to the second board 82. The first board 80 is higher than the second board 82. That is, the first board 80 and the second board 82 are positioned at different heights. The substrate 70 can be manufactured by way of pressing to form the metal sheets 78, which are spaced apart and arranged in an alternating manner, and the middle board 94 positioned in the middle of the substrate. Thus, the substrate 70 can be manufactured easily.

In this embodiment, the frame layer 72 is directly formed at the periphery of and bottom of the substrate, or formed around and under the substrate, by injection molding using the thermal plastic material and an injection mold. The frame layer 72 combines the metal sheets 78 with the middle board 94. A cavity 86 is formed between the frame layer 72 and the substrate 70. The top surface of the first board 80 and the bottom surface of the second board 82 are exposed from the frame layer 72. That is, the bottom surface of the first board 80 and the top surface of the second board 82 are covered by the frame layer 72. The bottom surface of the second board 82 is electrically connected to a printed circuit board (not shown).

The photosensitive chip 74 is placed on the middle board 94 and within the cavity 86.

The wires 88 electrically connect the bonding pads 90 formed on the photosensitive chip 74 to the top surfaces of the first boards 80, respectively. Therefore, signals from the photosensitive chip 74 can be transferred to each metal sheet 78 via the wires 88.

The transparent layer 76 may be a piece of transparent glass and may be bonded to the frame layer 72 by an adhesive layer 92, thereby covering the photosensitive chip 74 that may receive optical signals passing through the transparent layer 76.

According to the structure of the image sensor, the following advantages can be obtained.

1. Using the metal sheets 78, which are spaced apart, arranged in an alternating manner, and serve as the contact points for signal outputs, to form the substrate 70, the cost for forming the traces on the substrate in the prior art can be saved. Therefore, the manufacturing cost can be effectively lowered.

2. Using the injection molding method for directly forming the frame layer 72 and combining the metal sheets 78, the bonding process of the prior art can be simplified. In addition, the adhesive layer is free from overflowing during the cutting process, thereby effectively improving the production yield.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. An image sensor, comprising:
a substrate including plural metal sheets, which are spaced apart and arranged in an alternating manner, each of the metal sheets including a first board and a second board positioned at different heights;
a frame layer formed around and under the substrate to form a cavity with the substrate, each of the first boards having a top surface exposed from the frame layer, each of the second boards having a bottom surface, which is exposed from the frame layer and serves as contact points for signal outputs;
a photosensitive chip positioned within the cavity;
a plurality of wires electrically connecting the top surfaces of the first boards to the photosensitive chip; and
a transparent layer placed on the frame layer to cover the photosensitive chip.

2. The image sensor according to claim 1, wherein the frame layer is made of a thermal plastic material by way of injection molding.

3. The image sensor according to claim 1, wherein each of the metal sheets further includes a third board connecting the first board to the second board.

4. The image sensor according to claim 1, wherein the transparent layer is a piece of transparent glass.

5. The image sensor according to claim 1, wherein the substrate further comprises a middle board, which are arranged in a zone enclosed by the metal sheets and apart form the metal sheets, and the photosensitive chip is placed on the middle board.
